(19) United States
(12) Patent Application Publication
(10) Pub. No.: US 2008/0314446 A1
(43) Pub. Date: Dec. 25, 2008

(54) PROCESSES FOR THE PREPARATION OF SOLAR-GRADE SILICON AND PHOTOVOLTAIC CELLS

(75) Inventors: Thomas Francis McNulty, Ballston Lake, NY (US); John Thomas Leman, Niskayuna, NY (US); Larry Neil Lewis, Scotia, NY (US); Mark Philip D'Evelyn, Niskayuna, NY (US); Victor Lienkong Lou, Schenectady, NY (US); Roman Shuba, Niskayuna, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: GENERAL ELECTRIC COMPANY, Schenectady, NY (US)

(21) Appl. No.: 11/767,957

(22) Filed: Jun. 25, 2007

(51) Int. Cl. H01L 31/00; C01B 33/021

(52) U.S. Cl. 136/261; 423/349

(57) ABSTRACT

A process for the manufacture of high-purity elemental silicon is described. The process includes the step of preparing a silica gel composition by reacting at least one organosilane compound with an aqueous composition, so as to form granules of the silica gel. A hydrocarbon species is then decomposed by way of a hydrocarbon cracking reaction in the presence of the silica gel composition, so that carbon resulting from the decomposition of the hydrocarbon species is deposited on the granules of the gel composition. Heating of the carbon-containing silica gel composition to an elevated temperature produces the elemental silicon product. Related methods for making photovoltaic cells, using the elemental silicon, are also described.

### BACKGROUND OF THE INVENTION

The invention relates to a method of forming elemental silicon. More particularly, the invention relates to the preparation of solar-grade silicon that can be used by the photovoltaic (“PV”) industry for production of crystalline silicon-based PV modules.

Traditionally, the PV industry relies on silicon produced for the electronic industry for its silicon feedstock. Until about the year 2000, the silicon feedstock for the PV industry consisted of off-grade or reject-material from the semiconductor industry. Currently, prime-grade material (e.g., surplus), rejects and scraps from the electronic industry are typically used as feedstock. For the electronic industry, the cost of silicon feedstock is less than 5% of the device cost, whereas for the PV industry, it may be as much as 30% of the module cost. Because of tremendous growth in the PV industry, the main source of silicon is now prime-grade silicon. Ultimately, the cost of silicon could be the limiting factor in the cost of electricity produced by PV devices. Consequently, a low-cost source of solar-grade (SoG) silicon could become an enabling technology for widespread PV use.

The processes used for producing so-called prime-grade silicon are nearly identical to those used in producing semiconductor grade silicon. However, the producers have simplified some steps in their processes for supplying the PV industry. Due to cost considerations, there have been many attempts to replace the current purification process, based on chemical gaseous purification, with cheaper alternatives. One exemplary technique involves metallurgical purification (condensed phase). Significant progress has been achieved during recent years, and several pilot plants have been put into operation. However, these materials have only been slowly introduced to the market. and generally have only been useful as “diluents” for prime-grade material.

Development of SoG silicon has been pursued in two major areas: (a) variation of electronic grade (EG) silicon production using chemical processing, and (b) upgrading metallurgical grade (MG) silicon production. Advances made in the chemical processing route have benefited the electronic industry, by lowering the price of EG silicon. However, the cost of this material remains undesirably high for PV applications.

By using the chemical processing route for producing SoG silicon, all impurities may be reduced to a level less than about 1 ppba. However, it may also be possible to produce high efficiency cells with metallic impurities as high as 0.1 ppma. Thus, it is possible that the feedstock may contain higher levels of impurities than EG silicon feedstock, without compromising solar cell performance.

Several methods for producing solar grade silicon are known, but most of these methods have one or more drawbacks related to processing and cost. Some of these methods are based on a carbothermic reduction of compounds of silicon, such as silica, and may require the raw material to be of high purity to produce solar-grade silicon. In order to meet these requirements from the PV industry, development of an economical process that can produce relatively pure SoG silicon is very much needed. The present invention addresses one or more of the foregoing problems in the production of solar-grade silicon.

### BRIEF DESCRIPTION OF THE INVENTION

One embodiment of this invention is directed to a process for the manufacture of high-purity elemental silicon, comprising the following steps:
(a) preparing a silica gel composition by a technique which comprises the reaction of at least one organosilane compound with an aqueous composition, so as to form granules of the silica gel;
(b) decomposing a hydrocarbon species by a hydrocarbon cracking reaction in the presence of the silica gel composition, so that carbon resulting from the decomposition of the hydrocarbon species is deposited on the granules of the gel composition; and
(c) heating the carbon-containing silica gel composition to a temperature above about 1550° C., to produce a product which comprises elemental silicon.

Another embodiment of the invention relates to a method for making a photovoltaic cell, comprising the steps of
(A) preparing high-purity elemental silicon, by heating a silica gel composition, or an intermediate composition derived from a silica gel composition, wherein the silica gel composition or intermediate composition comprises at least about 5% by weight carbon, and the heating temperature is above about 1550° C., so as to produce a product comprising elemental silicon;
(B) forming the elemental silicon into a semiconductor substrate; and
(C) forming at least one p-n junction within or upon the semiconductor substrate.

### DETAILED DESCRIPTION OF THE INVENTION

According to one embodiment of the present invention, a silica gel composition is heated under conditions that produce elemental silicon, as described herein. A primary constituent of the composition is the silica gel itself, which is commercially available in a variety of forms. (Silica gel is also described in many references, e.g., the “Kirk-Othmer Encyclopedia of Chemical Technology”, 3^{rd} Edition, Volume 21, pp. 1020-1032, which is incorporated herein by reference). In general, silica gel is a granular, porous form of silica. Usually, silica gel can be described more specifically as a coherent, rigid, continuous 3-dimensional network of spherical particles of colloidal silica. The gel structure typically contains both siloxane and silanol bonds. The pores may be interconnected, and may be at least partially filled with water and/or alcohol, depending upon the particular hydrolysis and condensation reactions used to prepare the gel.

The silica gels can be prepared by a variety of techniques, as described in the Kirk-Othmer text. Non-limiting examples include bulk-set, slurry, and hydrolysis processes. The gels can also be made directly from salt-free colloidal silica; or from the hydrolysis of pure silicon compounds, such as ethyl silicate or silicon tetrachloride.

In some preferred embodiments, the silica gel is prepared by the hydrolysis of various organosilanes. (As used herein, “acidolysis” and “basic hydrolysis” are considered to be within the scope of “hydrolysis”). For example, one or more organosilanes can be reacted with an aqueous composition like water and, optionally, with at least one compound selected from the group consisting of alcohols, acidic catalysts (e.g., organic acids), and basic catalysts (e.g., organic bases). The use of basic catalysts may be preferred in other embodiments. Moreover, the organosilane usually comprises a compound having the formula

SiH₂(R′)ₓCl_{y}(OR)_{z};

wherein 0≦w, x≦2; 0≦y, z≦4; w+x+y+z=4; y+z≧2; and R and R′ are each, independently, an alkyl, aryl, or acyl group. Non-limiting examples of the organosilanes are: Si(OCH₃)₄, SiH(OCH₃)₃, Si(OC₂H₅)₄, and SiH(OC₂H₅)₃. Combinations of any of the foregoing are also possible.

As those skilled in the art understand, different types of silica gel can have a variety of different characteristics. In general, gels are characterized by the shape, size, surface area, and density of the gel particles; the particle distribution; and the aggregate strength or coalescence of the gel structure. As described in the Kirk-Othmer text mentioned above, silica gels are often characterized as one of three types: regular density; intermediate density; and low density. Distinguishing factors relate to particle size, pore diameter; pore volume; surface area; solvent content (e.g., water content); and method of preparation.

In some specific embodiments, the average size of the silica gel particles will be in the range of about 0.01 micron to about 400 microns, and typically, in the range of about 0.1 micron to about 100 microns. Moreover, the silica gel particles will usually have an average surface area in the range of about 10 m²/gram to about 3,000 m²/gram. In some specific embodiments, the surface area may be in the range of about 100 m²/gram to about 1,000 m²/gram. Furthermore, the silica gel usually has a tap density in the range of about 0.5 gram/cc to about 1.2 grams/cc, and more often, in the range of about 0.7 gram/cc to about 1.0 gram/cc.

The silica gel can further be characterized in terms of its volatile content. Usually, the primary volatile component is water (in various forms), or related compounds or moieties. Examples include covalently-bound hydrogen, hydroxyl groups, and physisorbed water. In general, the total concentration of bound-hydrogen, hydroxyl groups, and physisorbed water is at least about 0.01 atomic percent. In some specific embodiments, the total concentration of these components is in the range of about 0.01 atomic percent to about 5 atomic percent. In some preferred embodiments, the total concentration of silica-bound hydrogen and hydroxyl groups is in the range of about 0.03 atomic percent to about 1 atomic percent. As described in the Kirk-Othmer text cited above, the percentage of water in the form of surface hydroxyl groups can be a useful characteristic, since a higher hydroxyl group-concentration at the surface can provide a greater capacity for adsorption of water and other polar molecules.

The purity of the starting material for solar-grade silicon may often have a significant effect on the properties of the final product. Thus, in preferred embodiments, the silica gel is washed and/or subjected to other techniques for purification. Non-limiting examples of the techniques include washing with water and/or compatible solvents, sometimes using washing solutions (e.g., ammonia-containing) which contain various other components or additives. Non-limiting examples of the additives include various ionic or non-ionic compounds. A variety of distillation or filtration techniques may also be employed. (As mentioned below, some of these techniques may also be used at a later stage, to wash and separate the final silicon product).

The purification steps for the silica gel can effectively remove various metallic impurities, such as boron and phosphorous. Thus, after those steps are undertaken, the concentration of boron and phosphorus, individually, should be below about 1 ppmw. In some preferred embodiments, the concentration is below about 0.1 ppmw (parts-per-million, by weight), and in some especially preferred embodiments, the concentration is below about 3 ppbw (parts-per-billion, by weight). (A higher purity level in the starting material can result in greater purity in the final product). The enhanced purity of the silica gel starting material, together with its modest cost (as compared to starting materials for conventional processes), represents a distinct processing advantage.

As alluded to previously, the particles forming the silica gel may be present in various forms, or may be modified to those forms. For example, if the initial material assumes a form that is more like a true colloid or “jelly”, it can subsequently be transformed into more of a pelletized or granular form. Various techniques are available for modifying or treating the gel. As an example, the gel can be pulverized and extruded with a binder. Alternatively, a hydrogel can be shaped during drying.

In the present application, the term “granules” usually refers to individual units (particles) of starting material, in contrast to, for example, a solid continuum of material such as a large block. Thus, the term encompasses units ranging from infinitesimal powder particulates with sizes on the micrometer scale (such as, for example, a 325 mesh powder), up to comparatively large pellets of material with sizes on the centimeter scale. In some embodiments, the granules have an average size in the range of from about 100 microns to about 3,000 microns.

The granules may comprise pure silica, and may be produced by milling larger silica particles. The granules may additionally be washed in mineral acids, such as, but not limited to, nitric acid, hydrochloric acid, hydrofluoric acid, aqua regia, fluorosilicic acid, sulfuric acid, perchloric acid, phosphoric acid, and any combination thereof, to improve the purity of silica. In certain other embodiments, the granules are agglomerates, such as pellets. The median size of the pellets is typically on the millimeter-centimeter scale. In some embodiments, the agglomerates are formed by mixing silica gel, powder or particles with a binding agent to form a mixture, and subjecting the mixture to drying; partial/full decomposition of the binding agent by evaporation of solvent; or by baking or heating. Exemplary binding agents include hydrocarbons, sugars, cellulose, carbohydrates, polyethylene glycols, polysiloxanes, and polymeric materials. (As further described below, the granules themselves may be treated with a carbonaceous agent, prior to higher-temperature heat treatments).

As mentioned above, the silica gel composition comprises carbon, either initially, or by way of addition. The carbon source reduces the silica gel, forming elemental silicon. In one embodiment, the silica gel contains no carbon initially, or contains an amount of carbon that is insufficient for the reduction reaction employed to form substantial amounts of elemental silicon. In this embodiment, carbon from a separate source—solid, liquid, or gaseous—is combined with the silica gel. Non-limiting examples of the carbon source include carbon black, graphite, silicon carbide, at least one hydrocarbon (e.g., methane, butane, propane, acetylene, or combinations thereof), or natural gas.

Various techniques can be used to combine the carbon with the silica gel. In the case of solid carbon materials, conventional mixing techniques can be employed. In the case of a gaseous carbon source such as natural gas, a “cracking reaction” could be used to deposit carbon on granules of the silica gel particles. Related techniques for providing carbon-containing coatings on silica granules are described in U.S. patent application Ser. No. 11/497,876 (T. McNulty et al). This pending application was filed on Aug. 3, 2006, and is incorporated herein by reference. In general, those skilled in the art will be familiar with a variety of other methods for combining the carbon with the silica gel. (In some instances, the use of a hydrocarbon-based material as the carbon source is very advantageous, in view of its lower cost, as compared to carbon sources such as high-purity carbon black).

The appropriate amount of carbon present will depend on various factors, such as the amount of silica in the gel composition; the amount of water or other volatile or decomposable components; and the amount of volatile silicon monoxide (SiO, an intermediate compound) which is lost during the high-temperature reaction to form silicon. In general, the silica gel composition usually comprises at least about 5% by weight total carbon, based on the total weight of silica and carbon. (The carbon content may be measured by various techniques after treatment with the carbon source is completed, e.g., by a loss-on-ignition test). In some specific embodiments, the gel composition comprises at least about 15% by weight carbon. In embodiments which are sometimes preferred, the gel composition comprises at least about 25% by weight carbon. Those skilled in the art will be able to select the most appropriate level of carbon, based in part on the factors described herein.

In other embodiments, the silica gel may already contain an amount of carbon sufficient to carry out the reduction reaction to form elemental silicon. For example, the gel may be synthesized from an organosilane that contains bound carbon-containing groups which remain in place after hydrolysis. Examples include various alkyl, aryl, alkoxy, or aryloxy groups.

Moreover, in some situations, an intermediate composition derived from the silica gel composition may be used to form elemental silicon. As used herein, an “intermediate composition” refers to any composition that is formed from a silica gel composition by physical techniques, chemical techniques, or a combination of physical and chemical techniques. As an example, the silica gel composition can be partially- or fully calcined, forming an intermediate composition.

Calcination techniques typically involve treatment of a material at relatively high temperatures, though the heat treatment is usually carried out below the melting point of the material, i.e., below the melting point of silica in this instance. Calcination removes at least a portion of the volatile component of the silica gel composition, and may also transform all or part of the silica gel material into a different composition. For example, the silica gel can be transformed into synthetic silica or “synthetic sand” through calcination.

Moreover, if the silica gel initially contained carbon, or carbon was incorporated into the silica during the calcination step, the resulting calcination products can be synthetic silica, silicon carbide, silicon oxycarbide, or various combinations thereof. Calcination treatment schedules can vary considerably. Usually, calcination for embodiments of this invention involves heating temperatures in the range of about 50° C. to about 1500° C., for about 1 hour to about 1,000 hours. (Higher temperatures may compensate for shorter treatment times, while longer treatment times may compensate for lower temperatures).

Calcination can be advantageous for various reasons. For example, the removal of water by this technique can greatly improve the efficiency of the overall process, since water is not an active component of the reduction reaction, and usually must be partially or completely removed at some point during the production process. Moreover, calcination can improve the Theological properties of the silica gel intermediate composition, e.g., improving its “flowability” into the furnace for the reduction reaction. As described below, a prescribed heat treatment of the intermediate compositions results in the formation of the desired elemental silicon, in a manner similar to treatment of silica gel itself.

As mentioned previously, the silica gel composition is heated at a temperature sufficient to form elemental silicon, via chemical reduction. Heating can be carried out by various techniques. In some embodiments, induction or resistive heating is employed, using a suitable furnace, e.g., a vertical furnace or a horizontal rotary furnace.

The heating temperature will depend on various factors. Examples include the type of furnace used; the specific content of the silica gel composition; and the residence time of the material in the furnace; as well as reaction kinetics, e.g., gel particle size and powder mixedness (homogeneity). In preferred embodiments, heating is carried out at a temperature of at least about 1550° C., and preferably, at least about 1700° C. In some especially preferred embodiments, heating is carried out at a temperature of at least about 2,000° C. Other details regarding the heating step can be found in various references. Examples include U.S. Pat. No. 4,439,410 (Santen et al) and U.S. Pat. No. 4,247,528 (Dosaj et al), both of which are incorporated herein by reference.

As an alternative to the direct heating of the silica gel to form elemental silicon, the silica gel can first be heated to a temperature in the range of about 1550° C. to about 1800° C. Heating at this temperature results in the formation of an intermediate composition that comprises silicon carbide and volatile byproducts, including at least one of CO, H₂, H₂O, and CO₂. The intermediate composition comprising silicon carbide can then be reacted at higher temperatures, e.g., above about 2000° C., to form elemental silicon in molten form.

As another alternative alluded to previously, the silica gel can be transformed into various types of granules, as mentioned above, having a pre-selected average size. Carbon could then be deposited on at least a portion of the surface of the granules, e.g., by the decomposition of methane or another hydrocarbon. (The hydrocarbon cracking reaction was exemplified above). Thus, the carbon-containing silica granules can also serve as the “intermediate composition”, which is subsequently reacted to form elemental silicon.

In some preferred embodiments, many of the process steps described above are carried out continuously. In some instances, substantially all of the process steps are carried out continuously, e.g., from the step of feeding the silica gel and a carbon source (or a gel which already contains carbon) into the furnace, to the step of extracting the elemental silicon from the furnace. Optional steps, such as pre-heating or partial calcination of the silica gel, can also be carried out in the same furnace. Granulization of the silica gel can also be carried out as a sub-step of the above-described continuous processes. Moreover, coating of the silica gel granules by carbon can be carried out in-situ.

The elemental silicon formed by the methods of this invention can be separated and purified by a number of techniques that are well-known in the art. As a non-limiting example, a variety of washing, distillation, and filtration techniques could be employed. Moreover, the silicon powder product can be subjected to various thermal processes (e.g., plasma techniques), which enhance purity by melting-solidification-remelting cycles, for example. Those skilled in the art will be able to determine the most appropriate separation and purification steps for a given situation, based in part on the teachings herein. These steps can also be part of a continuous sequence originating with treatment of the silica gel. The process described herein can result in the formation of commercially-viable quantities of high-purity elemental silicon.

In terms of boron and phosphorus content, the elemental silicon prepared by the methods described herein generally has a purity level which is comparable to or higher than that of silicon produced by conventional techniques, e.g., by the typical carbothermic reduction of quartz sand or other forms of natural silica. This finding is somewhat surprising, since the process appears to be simpler and more economical than those of the prior art. As an illustration, the elemental silicon prepared according to this invention is thought to be immediately useable for photovoltaic substrate fabrication, without a number of subsequent processing steps, such as thorough drying and particle size classification. While such steps are certainly optional, the added flexibility in not always having to undertake them is an important manufacturing consideration.

In general, the elemental silicon (prior to any additional purification steps) usually has a boron content no greater than about 1 ppmw, and a phosphorous content no greater than about 1 ppmw. In some specific embodiments, the elemental silicon has a boron content no greater than about 0.1 ppmw, and/or a phosphorus content no greater than about 0.1 ppmw. For embodiments which are especially preferred for certain end uses, the elemental silicon has a boron content no greater than about 0.03 ppmw, and/or a phosphorus content no greater than about 0.03 ppmw.

The elemental silicon obtained by the invention can be utilized directly in solar cell manufacturing processes. However, additional product treatment steps can also be employed. For example, a molten product can be subjected to further purification steps, such as removal of residual silicon carbide particles by sedimentation. Directional solidification can be employed to remove transition metal impurities. Further purification steps can provide the product with a purity sufficient for electronic grade applications.

Another aspect of this invention relates to a method for making a photovoltaic cell. The method comprises the steps of forming a semiconductor substrate from elemental silicon prepared as described herein. The substrate material may be in monocrystalline or polycrystalline form, and can be provided with a selected type of conductivity according to known procedures. A monocrystalline substrate may be prepared by Czochralski or float-zone growth of a boule, followed by sawing and polishing. A multicrystalline substrate may be formed by casting and directionally-solidifying an ingot, followed by sawing and polishing. (Those skilled in the art are familiar with many other conventional details regarding formation of the substrate).

In a typical fabrication process, at least one p-n junction is formed within or upon the substrate. As an illustration, a p-n junction may be formed by diffusing phosphorus from a suitable source (e.g., phosphorus oxychloride, POCl₃) into a p-type, boron-doped silicon substrate. (As those skilled in the art understand, the electric field established across the p-n junction results in the formation of a diode that promotes current flow in only one direction across the junction, and promotes separation and collection of electron-hole pairs formed by the absorption of solar radiation). As another illustration, a p-n junction may be formed by the deposition of two layers of amorphous hydrogenated silicon upon the surface of the substrate, with the initial layer undoped, and the second layer doped with a polarity opposite that of the substrate, so as to form a p-n junction.

Other conventional steps are also typically undertaken in preparing the photovoltaic cells, e.g., the formation of metal-semiconductor contacts between various n-type and p-type regions of the cell; the formation of other metallization pathways and connections to an external load; as well as various etching, surface-texturing, gettering, passivation, and cleaning steps. Those of ordinary skill in the art will be able to readily determine the most appropriate fabrication procedures for a desired photovoltaic cell.

While preferred embodiments have been set forth for the purpose of illustration, the foregoing description should not be deemed to be a limitation on the scope of the invention. Accordingly, various modifications, adaptations, and alternatives may occur to one skilled in the art without departing from the spirit and scope of the claimed inventive concept. All of the patents, patent applications (including provisional applications), articles, and texts which are mentioned above are incorporated herein by reference.

1. A process for the manufacture of high-purity elemental silicon, comprising the following steps:
(a) preparing a silica gel composition by a technique which comprises the reaction of at least one organosilane compound with an aqueous composition, so as to form granules of the silica gel;
(b) decomposing a hydrocarbon species by a hydrocarbon cracking reaction in the presence of the silica gel composition, so that carbon resulting from the decomposition of the hydrocarbon species is deposited on the granules of the gel composition; and
(c) heating the carbon-containing silica gel composition to a temperature above about 1550° C., to produce a product which comprises elemental silicon.

2. The process of claim 1, wherein the organosilane comprises a compound having the formula SiH_{w}(R′)ₓCl_{y}(OR)_{z}; wherein 0≦w, x≦2; 0≦y, z≦4; w+x+y+z=4; y+z≧2; and
R and R′ are each, independently, selected from the group consisting of alkyl groups, aryl groups, and acyl groups.

3. The process of claim 2, wherein the organosilane is selected from the group consisting of Si(OCH₃)₄, SiH(OCH₃)₃, Si(OC₂H₅)₄, SiH(OC₂H₅)₃, and a combination of any of the foregoing.

4. The process of claim 1, wherein step (c) is carried out in a vertical furnace.

5. The process of claim 1, wherein the aqueous composition comprises water.

6. The process of claim 1, carried out as a continuous process.

7. The process of claim 1, wherein step (a) is carried out in the presence of at least one additional compound selected from the group consisting of an alcohol, an acidic catalyst, and a basic catalyst.

8. The process of claim 1, wherein the silica gel composition is washed, after step (a).

9. The process of claim 1, wherein the silica gel composition comprises boron.

10. The process of claim 9, wherein the concentration of boron is below about 1 ppmw.

11. The process of claim 1, wherein the silica gel composition comprises phosphorous.

12. The process of claim 11, wherein the concentration of phosphorous is below about 1 ppmw.

13. The process of claim 1, wherein the elemental silicon is separated and purified.

14. The process of claim 13, wherein purification is carried out by a technique that comprises washing.

15. The process of claim 1, wherein the average silica particle size in the silica gel composition of step (c) is in the range of about 0.01 micron to about 400microns.

16. The process of claim 1, wherein the granules of the silica gel composition have an average surface area in the range of about 10 m²/gram to about 3,000 m²/gram.

17. A method for making a photovoltaic cell, comprising the steps of
(A) preparing high-purity elemental silicon, by heating a silica gel composition, or an intermediate composition derived from a silica gel composition, wherein the silica gel composition or intermediate composition comprises at least about 5% by weight carbon, and the heating temperature is above about 1550° C., so as to produce a product comprising elemental silicon;
(B) forming the elemental silicon into a semiconductor substrate; and
(C) forming at least one p-n junction within or upon the semiconductor substrate.

18. A method for making a photovoltaic cell, comprising the steps of
(i) preparing a silica gel composition by a technique which comprises the reaction of at least one organosilane compound with an aqueous composition, so as to form granules of the silica gel;
(ii) decomposing a hydrocarbon species by a hydrocarbon cracking reaction in the presence of the silica gel composition, so that carbon resulting from the decomposition of the hydrocarbon species is deposited on the granules of the gel composition;
(iii) heating the carbon-containing silica gel composition to a temperature above about 1550° C., to produce a product which comprises elemental silicon;
(iv) separating the elemental silicon;
(v) forming the elemental silicon into a semiconductor substrate; and
(vi) forming at least one p-n junction within or upon the semiconductor substrate.

19. The method of claim 18, wherein the aqueous composition comprises water.

20. The method of claim 18, wherein the organosilane comprises a compound having the formula SiH_{w}(R′)ₓCl_{y}(OR)_{z}; wherein 0≦w, x≦2; 0≦y, z≦4; w+x+y+z=4; y+z≧2; and
R and R′ are each, independently, selected from the group consisting of alkyl groups, aryl groups, and acyl groups.

21. The method of claim 20, wherein the organosilane is selected from the group consisting of Si(OCH₃)₄, SiH(OCH₃)₃, Si(OC₂H₅)₄, SiH(OC₂H₅)₃, and a combination of any of the foregoing.
